(19) United States
(12) Patent Application Publication
(10) Pub. No.: US 2026/0025140 A1
(43) Pub. Date: Jan. 22, 2026

(54) METHOD OF OPERATING ASYNCHRONOUS FINITE STATE MACHINE CIRCUITS AND CORRESPONDING FINITE STATE MACHINE CIRCUIT

(71) Applicant: STMicroelectronics International N.V., Geneva (CH)

(72) Inventors: Enea Dimroci, Borgo San Dalmazzo (IT); Riccardo Pellegrini, Rho (IT); Enrico Papa, Arvier (AO) (IT)

(21) Appl. No.: 19/270,228

(22) Filed: Jul. 15, 2025

(30) Foreign Application Priority Data
Jul. 17, 2024 (IT) 102024000016480

(51) Int. Cl. H03K 19/003; H03K 5/1252; H03K 19/0185

(52) U.S. Cl. CPC H03K 19/00384; H03K 5/1252; H03K 19/018557

(57) ABSTRACT

An asynchronous finite state machine (FSM) circuit comprises an arc cell configured to receive an analog input signal candidate for propagation over the FSM circuit as an output signal from the arc cell. In response to glitch affecting the analog input signal to the arc cell propagation over the FSM circuit of the analog input signal affected by glitch is conditioned upon either one of: i) the glitch being suppressed at the output of the arc cell, or ii) the glitch being latched within the arc cell. Propagation over the FSM circuit of the analog input signal affected by glitch takes place in response to the glitch being suppressed at the output of the arc cell irrespective of the glitch being latched within the arc cell.

### CROSS-REFERENCE TO RELATED APPLICATIONS

This application claims the benefit of Italian Patent Application No. 102024000016480, filed on Jul. 17, 2024, which application is hereby incorporated herein by reference.

### TECHNICAL FIELD

The description relates to finite state machines (FSMs).

Aspects of the present description can be used, for instance, in a variety of devices such as, merely by way of example, display drivers (direct current (DC)-DC drivers for active-matrix organic light-emitting diode (AMOLED) display devices), power management integrated circuits (PMICs), rectifiers, preamplifiers for disk storage applications.

### BACKGROUND

The designation Finite State Machine (FSM), derived from a mathematical model of computation, applies to a machine that can be in one of a finite number of states at any given time and changes from one state to another (thus undergoing a so-called “transition”) in response to an input received.

An FSM is defined by a list of states starting from an initial state and by the inputs that trigger transitions between states.

While per se designating an abstract model, FSM behavior underlies operation of many devices configured to perform a predetermined sequence of actions based on a sequence of events.

An FSM can be implemented in the form of an electrical circuit. A computer or controller may be exemplary of such a circuit.

While used in its simplest form for brevity, throughout this description the designation “FSM circuit” or “FSM” is intended to refer to “an electrical circuit implementing the FSM model”.

A computer or controller may be used to implement such an FSM circuit. A main motivation of using digital circuitry operating according to an FSM paradigm (in short, an FSM circuit) lies in the inherent high complexity of corresponding analog circuitry.

Good performance of these application benefits from operating at high clock frequencies, in the range of hundreds of MHz for instance, which is hardly feasible from a power consumption perspective.

Asynchronous FSM operation dispenses with the availability of a clock signal, which facilitates achieving adequate performance without undesirably increasing power consumption.

Asynchronous FSM design and implementation benefit from the fact that a request/acknowledge mechanism underlying operation of such FSM circuits can be triggered via asynchronous signals in the analog domain.

For that reason, asynchronous design of FSM circuits is used in a variety of applications. Power management, rectifiers, pre-amplifiers for hard disk memories have already been mentioned as possible examples of these applications.

An issue with this design lies in that asynchronous signals may “glitch”, and thus undergo an aperiodic transient such as a short, unpredictable peak or occur in combinations likely to create hazard events.

These glitches can propagate through an FSM circuit possibly giving rise to undesirable request/acknowledge events that may in turn result in deadlock situations and/or unknown states of the asynchronous FSM.

Conventional solutions to address these issues involve: Min_TON and Min_TOFF analog circuitry to set minimum controllable on-times and off-times to enlarge a glitch; comparators designed to be glitch-free used to produce the input signals of the asynchronous design; or redundant asynchronous design.

These solutions may suffer from various drawbacks such as increased area occupation, power consumption and latency.

### SUMMARY

An object of one or more embodiments is to contribute in addressing the issues discussed in the foregoing.

According to one or more embodiments, such an object can be achieved via a method having the features set forth in the claims that follow.

One or more embodiments relate to a corresponding asynchronous finite state machine (FSM) circuit.

A power management integrated circuit (PMIC), a rectifier, a preamplifier for disk storage may be non-limiting examples of such a circuit.

The claims are an integral part of the disclosure provided herein in respect of the embodiments.

### BRIEF DESCRIPTION OF THE DRAWINGS

One or more embodiments will now be described, by way of example only, with reference to the annexed figures, wherein:

FIG. 1 is a block diagram providing an elementary representation of an FSM circuit;

FIG. 2 is a flow-chart exemplary of possible operation of an arc cell in an FSM circuit as illustrated in FIG. 1;

FIG. 3 is a diagram exemplary of a possible implementation of an arc cell in an FSM circuit as illustrated in FIG. 1;

FIG. 4 is a circuit diagram exemplary of a possible implementation of one of the blocks in FIG. 3;

FIG. 5 is a time diagram exemplary of possible time behaviors (waveforms) of signals that may occur in an arc cell in an FSM circuit as illustrated in FIG. 3 and FIG. 4 in response to an input glitch;

FIG. 6 is a flow-chart exemplary of a possible approach in countering undesired effects of input glitches in an arc cell in an FSM circuit according to solutions described herein;

FIG. 7 is a circuit diagram exemplary of a possible modification of the arc cell of FIG. 3 and FIG. 4 aimed at countering undesired effects of input glitches according to solutions described herein; and

FIGS. 8 and 9 are time diagrams exemplary of possible time behaviors (waveforms) of signals that may occur in an arc cell in an FSM circuit as illustrated in FIG. 7.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

Once more, for the sake of simplicity and ease of explanation:
a same designation may be applied throughout this description to designate a certain node or line as well as a signal occurring at that node or line;
a same designation may be applied throughout this description to designate certain component (such as a capacitor, resistor or inductor of coil) as well as electrical parameters thereof;
as used herein, the designation Finite State Machine, FSM circuit (in short, FSM) is intended to indicate “an electrical circuit implementing an FSM model”.

By way of background (and as known to those of skill in the art) a basic idea underlying an FSM is to store a sequence of different states and transitions between them depending on the values of the inputs and the current state of the machine.

An FSM can be of two types: Moore (where the output of the state machine is purely dependent on the state variables) and Mealy (where the output can depend on the current state variable values AND the input values).

The procedure for designing an FSM (more to the point, designing an electrical circuit implementing such an FSM) involves steps such as:
identifying inputs and outputs;
defining a state transition diagram;
writing a state transition table and an output table (for a Moore machine) or a combined state transition and output table (for a Mealy machine);
selecting state encodings, with selection affecting the hardware design;
writing Boolean equations for the next state and output logic;
devising a corresponding circuit diagram.

As noted, FSM circuits can be described by mathematical models.

These can be implemented as asynchronous FSMs, as Moore machines where the outputs are purely dependent on the active state.

The related art is quite extensive, including patent literature placing emphasis on arc cells. It is noted that an “arc”, as repeatedly mentioned herein, is oftentimes referred to an “edge” of a graph, in so far as an FSM can be described by a graph.

For instance, document WO 2009/144576 A1 discloses a method of specifying a finite state machine so that instructions for instantiating the state machine are specified in an application file and parameters relating to the states, events and transitions of the state machine arcs are specified in a resource file, independent of the application file. Furthermore, a method of specifying a state machine so that the state machine is capable of passing information such as return messages as a result of undergoing a transition. A plurality of state machines is capable of passing information between one another.

Document US 2014/156274 A1 discloses methods and systems to translate input labels of arcs of a network, corresponding to a sequence of states of the network, to a list of output grammar elements of the arcs, corresponding to a sequence of grammar elements. The network may include a plurality of speech recognition models combined with a weighted finite state machine transducer (WFST). Traversal may include active arc traversal, and may include active arc propagation. Arcs may be processed in parallel, including arcs originating from multiple source states and directed to a common destination state. Self-loops associated with states may be modeled within outgoing arcs of the states, which may reduce synchronization operations.

Document U.S. Pat. No. 6,249,761 B1 discloses a continuous, speaker independent, speech recognition method and system capable of recognizing a variety of vocabulary input signals. A language model in the form of a graph consisting of a plurality of states and arcs is input into the system. An input speech signal, corresponding to a plurality of speech frames, is received and processed using a shared memory multipurpose machine having a plurality of microprocessors. Threads are created and assigned to processors, and active state subsets and active arc subsets are created and assigned to specific threads and associated microprocessors. Active state subsets and active arc subsets are processed in parallel to produce a textual representation of the speech signal.

Solutions as described herein facilitate implementing asynchronous FSM circuits that can be regarded as essentially glitch-free or glitch-exempt in so far undesired propagation of request/acknowledge signals is effectively countered thus facilitating implementing asynchronous FSMs for which any possible state can be reasonably assumed to a known state, with the ability to “filter out” glitches or other detrimental events likely to affect asynchronous FSMs.

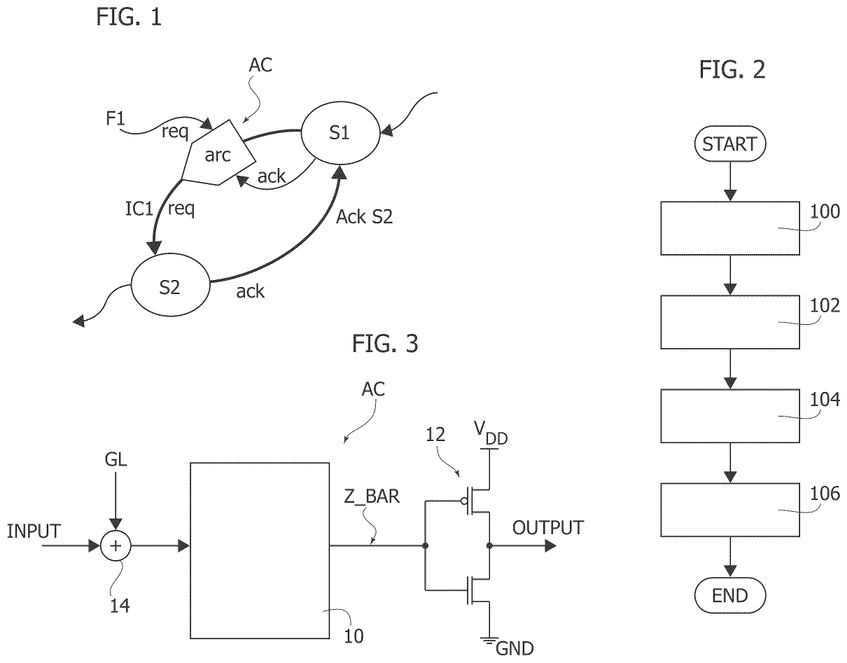

The states in an FSM (circuit) can be conventionally represented by nodes such as S1 and S2 in FIG. 1.

A “nutshell” representation of an FSM including just two states/nodes is reproduced in FIG. 1 for simplicity and ease of explanation: in fact, an FSM can include any number (including very large numbers) of states/nodes.

FIG. 1 represents, by way of non-limiting example, a handshake (is the process that kicks off a communication) between two states S1 and S2 in an asynchronous FSM (AFSM, in short).

Arc cells AC are used to represent the inter-state transitions that take place based on request signals (indicated req) and acknowledgement signals (indicated ack).

A concept that underlies solutions as described herein is to configure cells in an FSM to counter (avoid) triggering a “next” stage until the cell has latched the input.

Such a cell can be used as an arc cell in AFSMs (Asynchronous Finite State Machines).

The result will be that the first request of the request acknowledge mechanism is free from possible glitches: in that way a deadlock of the AFSM is avoided in so far as the request is stable.

FIG. 1 is exemplary of the possibility of applying the FSM (circuit) design procedure discussed previously, to generate-starting from an FSM description—an asynchronous circuit including:
states S1 and S2,
arcs such as AC and F1,
request (req) and acknowledge (ack) signals complying with a protocol.

At least in principle, a triggering arc (F1 in FIG. 1) should be stable until full protocol completion.

A corresponding exemplary protocol description (as represented in the flow-chart of FIG. 2) may be as follows:
F1->IC1 req to arc (a request signal req is sent to the arc cell AC—step 100 in FIG. 2)
IC1->S2 req to state (the request signal req is forwarded to the state S2—step 102 in FIG. 2)
S2->S1 ack to state (an acknowledgement signal ack—namely Ack S2—is sent to the state S1—step 104 in FIG. 2)
S1->IC1 ack to arc (an acknowledgement signal ack is forwarded from the state S1 to the arc cell AC—step 106 in FIG. 2)

It is noted that on an actual product (circuit) triggering arcs (such as F1 in FIG. 1) may be not really stable until full protocol completion.

For instance, a deadlock could be observed caused by glitch propagation through the arc cell AC.

As a consequence:
in response to glitch the arc cell is not set (that is IC1 req to arc in the exemplary protocol description does not properly take place);
a glitch propagation wave acknowledges (erroneously) the starting state (that is IC1->S2 req to state does not properly take place so that S2 is not set); and
S2->S1 ack to state takes place so that Ack to S1 triggered (erroneously).

FIG. 3 is a diagram exemplary of a possible implementation of an arc cell AC in an asynchronous FSM circuit as illustrated in FIG. 1.

The representation of FIG. 3 is deliberately general and takes into account the variety of possible options available to implement such a cell AC.

For the purposes herein, the cell AC can be regarded as including a (logic) core portion 10 having cascaded thereto a (metal-oxide-semiconductor field-effect transistor (MOSFET)-based, for instance) inverter 12 arranged between a supply bar V_{DD} and ground GND, with the inverter 12 driven by the core portion 10 via a line indicated as Z_BAR.

Such cell AC architecture in per se conventional and can be implemented in any manner known to those of skill in the art.

The cell AC as represented in FIG. 3 is configured to receive an input signal INPUT (the asynchronous request signal req represented by arc F1 in FIG. 1, for instance) and to deliver an output signal OUTPUT.

A glitch GL may affect the input signal INPUT as represented by a summation node 14. As used herein, the designation “glitch” generally applies to an aperiodic transient likely to create hazard events.

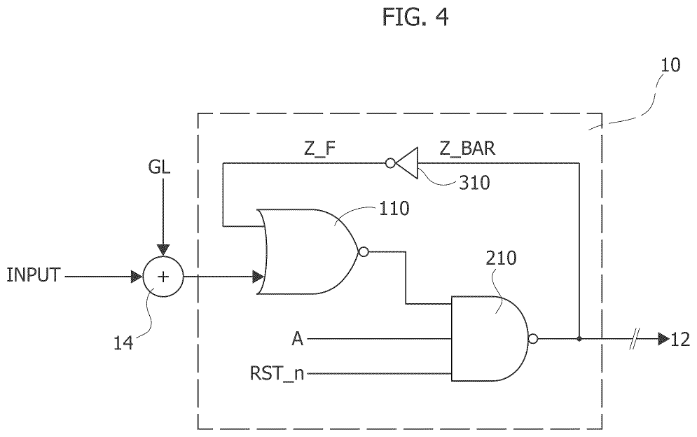

FIG. 4 is a circuit diagram exemplary of a possible implementation of the core portion 10 in FIG. 3.

In FIG. 4 references 110 and 210 indicate two logic gates (NOR 110 and NAND 210).

The logic gate 110 (NOR) receives:
as a first input, the input signal INPUT (possibly affected by glitch GL), and
as a second input, a feedback signal Z_F from a logic inverter 310.

The logic gate 210 (NAND) receives:
as a first input, the output signal from the logic gate 110,
as a second input, an enable signal indicated by A, and
as a third input, a reset signal RST_n.

The output signal from the logic gate 210 is the signal Z_BAR applied to the inverter 12.

It is again noted that, for the sake of simplicity and ease of explanation, a same designation may apply throughout this description to a certain node or line as well as a signal occurring at that node or line: the signal/line Z_BAR is an exemplary case in point.

The signal Z_F is an internal signal of the core portion 10, which includes a loop and the signal Z_F is feedback signal in this internal loop.

The two logical gates 110 and 210 are configured to provide a desired input-output logic function and also to give sequential property to the cell by via internal feedback.

The signal Z_BAR (used to generate the feedback signal Z_F via the logic inverter 310) produced in the core portion 10 drives the output stage 12 that in turn provides a signal OUTPUT to an (external) IC (not visible in the figures for simplicity), thus providing the output of the arc cell AC.

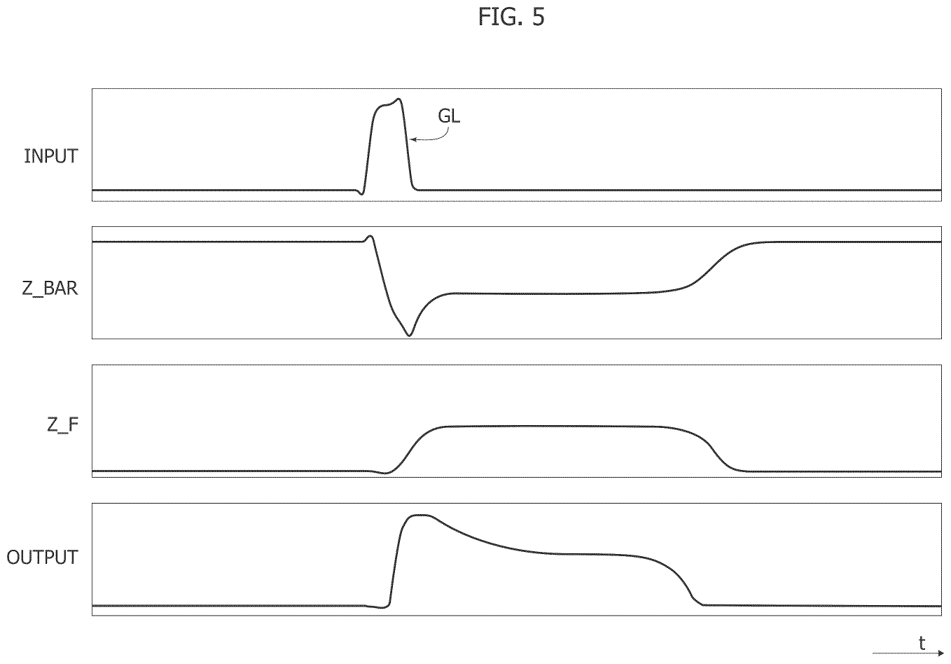

FIG. 5 is a diagram exemplary of possible time behaviors (waveforms) of signals that may occur in an arc cell in an FSM circuit as illustrated in FIG. 3 and FIG. 4 in response to an input glitch GL.

More specifically, FIG. 5 represents, against a common time abscissa scale t, possible corresponding time behaviors of (from top to bottom):
an input signal INPUT affected by glitch GL;
the signal Z_BAR,
the feedback signal Z_F in the internal loop of the core portion 10 and
an output signal OUTPUT from the arc cell AC.

Such a cell behavior in response to a possible glitch event GL (essentially a glitch GL at the input of the arc cell AC being propagated to the cell output in an undesired manner) may result in various drawbacks.

For instance, a glitch event GL can cause an undesired reset of a current state without setting of a new state, with a resulting “no active state” deadlock condition: this amounts to an FSM deadlock condition in so far as no state in the FSM circuit is ultimately active.

Also, a supply voltage (V_{DD}/2, for instance) can be undesirably propagated for longer than desired (more than 0.5 ns, for instance).

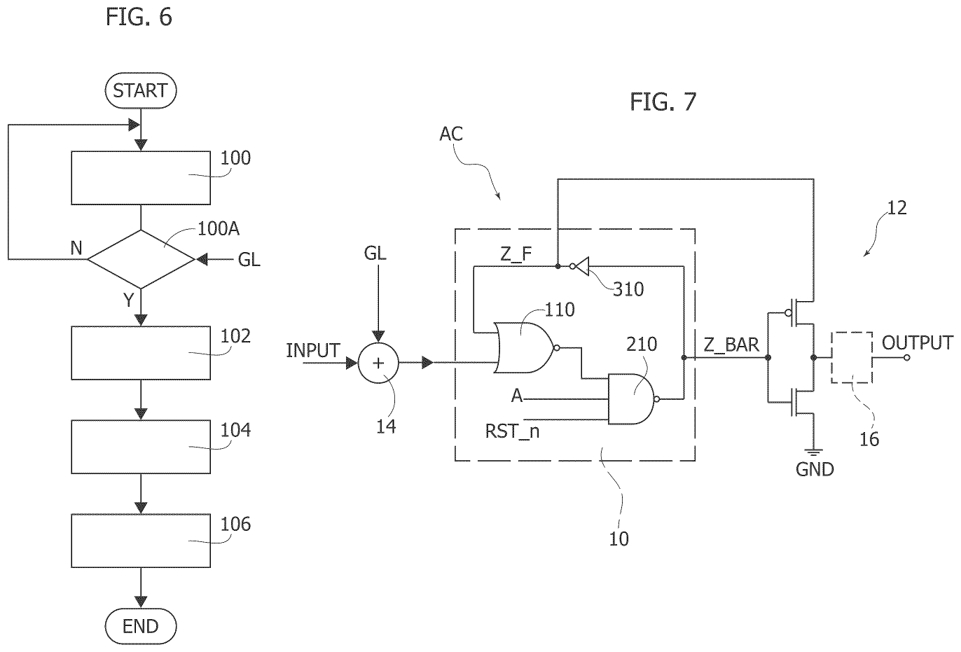

FIG. 6 is a flow-chart exemplary of a possible approach in countering undesired effects of input glitches in an arc cell in an FSM circuit.

The rationale underlying that approach is essentially to filter (out) the glitch GL within the arc cell AC so that the glitch GL is not undesirably propagated towards the cell output: by way of example, a logic “1” is propagated (as desired) towards the cell output only if the glitch GL is latched within the arc cell.

Such an approach is represented in the flow-chart of FIG. 6 by way of comparison with the flow-chart of FIG. 2, and like parts (steps) are indicated in both flow-charts with like reference numerals so that a corresponding description will not be repeated for FIG. 6.

Essentially, in the flow-chart of FIG. 6 the “propagation” steps 102, 104 and 106 are preceded by a check (represented by a block 100A) where, in the presence of a glitch event GL (which may be detected in a manner known per se), “propagation” as represented by steps 102, 104 and 106 is conditioned upon a positive outcome (“Y”) of the check 100A indicating that the glitch GL is completely suppressed at the output and thus not propagated to the cell output even if the glitch is not latched in the cell AC.

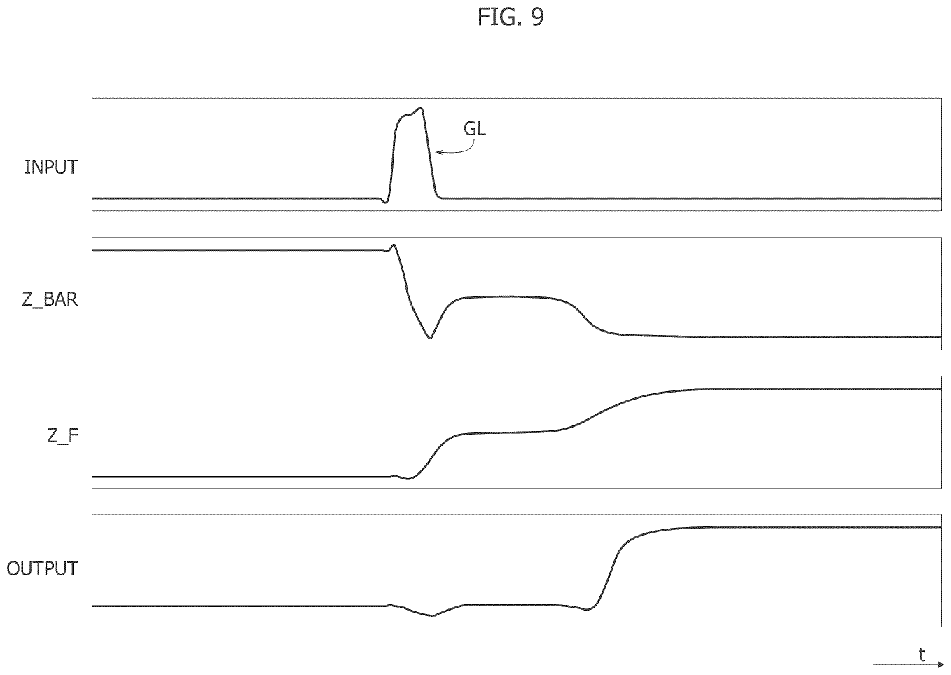

FIG. 9 (to be discussed later) illustrates a case where the glitch GL is effectively latched within the cell AC and is propagated to the output (only) in response to being latched.

Of course, in the representation of the flow-chart of FIG. 6 the outcome of the check 100A can be assumed to be positive (“Y”) in the absence of glitch so that the “propagation” steps 102, 104 and 106 are allowed in response to the absence of glitch revealed.

The representation in the flow-chart of FIG. 6 is primarily notional and as such also covers a possible SW implementation of the basic concept of countering undesired propagation of glitch GL towards the cell output.

A solution as described herein can likewise be implemented in a particularly advantageous manner at a HW (or FW) level by modifying the arc cell circuit of FIG. 3 and FIG. 4 as represented in FIG. 7.

In FIGS. 3 (plus 4) and in FIG. 7 like parts or elements are indicated with like reference symbols so that a corresponding description will not be repeated for FIG. 7.

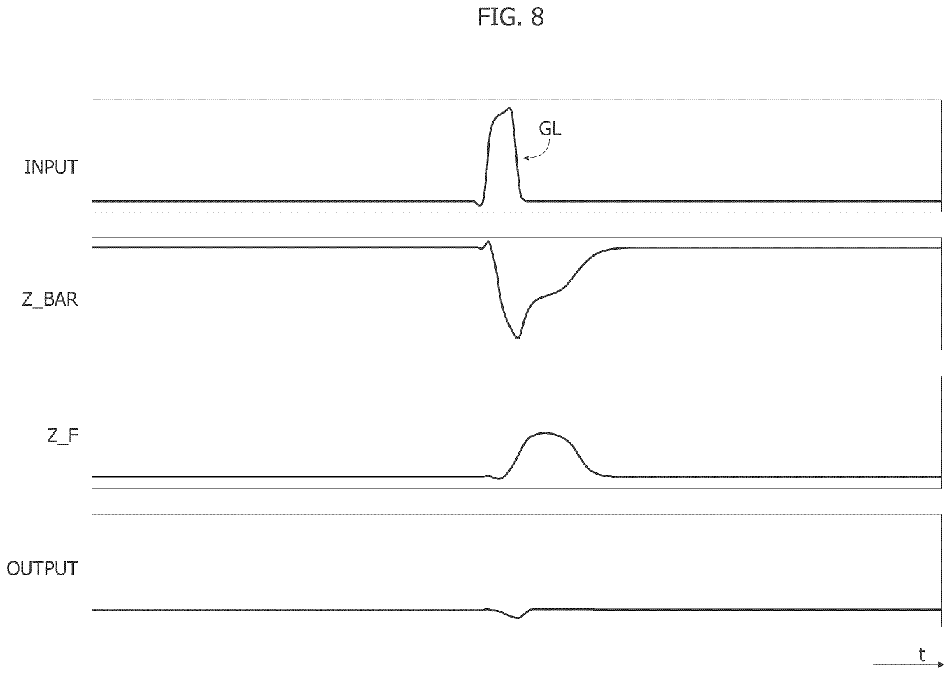

FIG. 7 is a circuit diagram exemplary of a possible modification of the arc cell AC of FIG. 3 and FIG. 4 wherein undesired effects of input glitches are effectively countered simply by using the (feedback) signal Z_F as a supply rail of the output inverter 12 so that the inverter 12 acts as a metastability solver so that:
i) as illustrated in FIG. 8, the glitch GL is completely suppressed at the output, with the glitch not latched in the cell AC and, in any case, not propagated in output;
ii) as illustrated in FIG. 9, the glitch GL is latched in the cell AC and is propagated to the output in so far as it is latched.

No metastability may thus occur in a cell AC as illustrated in FIG. 7.

To summarize, a cell AC as illustrated in FIG. 7 is exemplary of an asynchronous finite state machine, FSM circuit comprising an arc cell AC configured to receive (step 100 in the flow-chart of FIG. 6) an analog input signal INPUT which (see req in FIG. 1) is candidate for propagation over the FSM circuit as an output signal OUTPUT from the arc cell AC.

The arc cell AC as exemplified in FIG. 7 is configured, in response to glitch GL affecting the analog input signal INPUT, to condition (step 100A in the flow-chart of FIG. 6) propagation (steps 102, 104, 106 in the flow-chart of FIG. 6) over the FSM circuit of the analog input signal INPUT affected by glitch GL upon either one of the glitch GL being suppressed at the output of the arc cell AC (as exemplified in FIG. 8), or

the glitch GL being latched within the arc cell (as exemplified in FIG. 9).

More specifically, both FIGS. 8 and 9 represent, against common time abscissa scales t, possible corresponding time behaviors of (from top to bottom):
an input signal INPUT affected by glitch GL;
a signal Z_BAR on the line between the core logic 10 and the output inverter 12,
a (feedback) signal Z_F obtained by logically inverting (at the inverter 310) the signal Z_BAR; and
an output signal OUTPUT.

To summarize, as illustrated in FIG. 7:
the arc cell AC comprises core circuitry 10 configured to receive at an input (at the NOR gate 110) the analog input signal INPUT candidate for propagation over the FSM circuit as well as output circuitry (the MOSFET-based inverter 12) configured to produce the output signal OUTPUT from the arc cell AC;
the output circuitry 12 is driven (via the NAND gate 210) by the core circuitry 10 at a drive line (from the NAND gate 210) via a drive signal Z_BAR that admits a first value and a second value.

FIGS. 8 and 9 are representative of possible different possible time behaviors of the signals Z_BAR and Z_F in response to a same input signal INPUT affected by glitch GL.

In the case exemplified in FIG. 8, the glitch GL is completely suppressed at the output in so far as the signal Z_BAR rapidly recovers its pre-glitch level and the signal Z_L shows just a short “bump” that is not propagated to the cell output even if the glitch is not latched in the cell AC.

That is, in the case exemplified in FIG. 8, the output circuitry 12 is configured to condition propagation of the analog input signal INPUT over the FSM circuit upon the drive signal Z_BAR recovering its first value after glitch GL affecting the analog input signal INPUT is suppressed at the output 12 of the arc cell AC.

In the case exemplified in FIG. 9, the signal Z_BAR switches (from “high” to “low” for instance) in response to the glitch GL. Thus, the glitch is not suppressed per se but is however latched in the cell as exemplified by the signal Z_L and is propagated to the output of the cell AC in response to being latched therein. As illustrated, the cell output is supplied only in response to a logic “1” being latched in the cell. The output can change only in response to such a latching action occurring in the cell.

That is, in the case exemplified in FIG. 9, the output circuitry 12 is configured to condition propagation of the analog input signal INPUT over the FSM circuit upon the drive signal Z_BAR switching from the first value to the second value in response to glitch affecting the analog input signal INPUT with a cell latch signal (namely the signal Z_F) being asserted in response to glitch GL being latched within the arc cell AC.

Advantageously, the arc cell AC may be configured to facilitate propagation over the FSM circuit of the analog input signal INPUT affected by glitch GL in response to the glitch GL being suppressed at the output of the arc cell AC irrespective of the glitch GL being latched within the arc cell AC.

FIG. 7 is exemplary of an advantageous HW implementation of the general concept outlined in the flow-chart of FIG. 6.

The core circuitry 10 illustrated in FIG. 7 comprises a feedback path from the drive line (the output of the NAND gate 210) driving the output circuitry 12 wherein such a feedback path carries a feedback signal Z_F the input of the core circuitry 10 (the NOR gate 110); that feedback signal Z_F May thus provide a cell latch signal Z_F asserted in response to glitch GL being latched within the arc cell AC.

Advantageously, the feedback path from the drive line (gate 210) comprises a logic inverter 310 coupled to the drive line and configured to carry towards the input of the core circuitry 10 (the gate 110) a feedback signal Z_F which is a logically inverted replica of the drive signal Z_BAR that admits a first value and a second value.

As illustrated in FIG. 7, the output circuitry 12 is supplied via a supply node configured to have applied thereto the feedback signal Z_F.

Advantageously, the output circuitry 12 may comprise first and second MOSFET transistors arranged with the current flow paths therethrough in a current flow line between the supply node configured to have applied thereto the feedback signal Z_F and ground GND.

As illustrated by way of example, the output circuitry 12 comprises an inverter including first and second MOSFET transistors having respective control terminals commonly coupled to the drive line from the core circuitry 10 (the NAND gate 210); the first and second MOSFET transistors are arranged with the current flow paths therethrough cascaded to each other with an output node of the arc cell AC arranged therebetween.

Results as reported in FIG. 8 and FIG. 9 are confirmed by simulating a variety of different glitches width in nominal conditions, both in “best case” and in “worst case” corner conditions.

A glitch-robust arc cell AC as discussed herein can be advantageously included in an asynch IP library for FMS circuits.

An implementation based on connecting the supply rail of an output inverter in the cell (reference 12 in FIG. 7) to the Z_F node/line in the cell was found to be both simple and effective.

A buffer stage 16 (illustrated in dashed lines in FIG. 6) can be optionally added at the output of the inverter 12.

An arc cell AC as described herein effectively counters undesired effects (FSM deadlock, for instance) that may result from glitch on arc.

More generally (see the flow-chart of FIG. 6, for instance) an arc cell AC as described herein facilitates a glitch-free request-acknowledge mechanism in asynchronous design of FSM circuits (AFSMs), thus countering possibility of deadlock in AFSMs.

Without prejudice to the underlying principles, the details and embodiments may vary, even significantly, with respect to what has been described by way of example only, without departing from the extent of protection.

The extent of protection is determined by the annexed claims.

What is claimed is:

1. An asynchronous finite state machine (FSM) circuit comprising:
an arc cell configured to:
receive an analog input signal that is a candidate for propagation over the FSM circuit as an output signal from the arc cell; and
in response to a glitch affecting the analog input signal, condition the propagation over the FSM circuit of the analog input signal affected by the glitch upon either one of i) the glitch being suppressed at an output of the arc cell, or ii) the glitch being latched within the arc cell.

2. The FSM circuit of claim 1, wherein the arc cell is configured to facilitate the propagation over the FSM circuit of the analog input signal affected by the glitch in response to the glitch being suppressed at the output of the arc cell, irrespective of the glitch being latched within the arc cell.

3. The FSM circuit of claim 1, wherein the arc cell comprises core circuitry comprising:
an analog input configured to receive the analog input signal;
an enable input configured to receive an arc cell enable signal; and
a reset input configured to receive an arc cell reset signal.

4. The FSM circuit of claim 1, wherein the arc cell comprises:
core circuitry configured to receive at an input the analog input signal that is the candidate for the propagation over the FSM circuit; and
output circuitry driven by the core circuitry at a drive line via a drive signal admitting a first value and a second value, and configured to:
produce the output signal from the arc cell; and
condition the propagation of the analog input signal over the FSM circuit upon either one of i) the drive signal recovering its first value after the glitch affecting the analog input signal, wherein the glitch is suppressed at the output of the arc cell, or ii) the drive signal switching from the first value to the second value in response to the glitch affecting the analog input signal with a cell latch signal being asserted in response to the glitch being latched within the arc cell.

5. The FSM circuit of claim 4, wherein the core circuitry comprises a feedback path from the drive line carrying a feedback signal towards the input of the core circuitry, and wherein the feedback signal provides the cell latch signal asserted in response to the glitch being latched within the arc cell.

6. The FSM circuit of claim 5, wherein the feedback path from the drive line comprises a logic inverter coupled to the drive line, and is configured to carry towards the input of the core circuitry an inverted feedback signal that is a logically-inverted replica of the drive signal admitting the first value and the second value.

7. The FSM circuit of claim 5, wherein the output circuitry is supplied via a supply node configured to have applied thereto the feedback signal.

8. The FSM circuit of claim 7, wherein the output circuitry comprises first and second metal-oxide-semiconductor field-effect transistors (MOSFETs) arranged with current flow paths therethrough in a current flow line between the supply node configured to have applied thereto the feedback signal and a ground.

9. The FSM circuit of claim 4, wherein the output circuitry comprises an inverter including first and second MOSFET transistors having respective control terminals commonly coupled to the drive line from the core circuitry, and wherein the first and second MOSFET transistors are arranged with current flow paths therethrough cascaded to each other with an output node of the arc cell arranged therebetween.

10. The FSM circuit of claim 4, further comprising a buffer stage coupled downstream of the output circuitry.

11. A method of operating an asynchronous finite state machine (FSM) circuit, the method comprising:
receiving at an arc cell in the FSM circuit an analog input signal that is a candidate for propagation over the FSM circuit as an output signal from the arc cell; and
in response to a glitch affecting the analog input signal to the arc cell, conditioning the propagation over the FSM circuit of the analog input signal affected by the glitch upon either one of i) the glitch being suppressed at an output of the arc cell or ii) the glitch being latched within the arc cell.

12. The method of claim 11, further comprising facilitating the propagation over the FSM circuit of the analog input signal affected by the glitch in response to the glitch being suppressed at the output of the arc cell, irrespective of the glitch being latched within the arc cell.

13. The method of claim 11, further comprising:
receiving, at an input of core circuitry of the arc cell, the analog input signal that is the candidate for the propagation over the FSM circuit;
driving, by the core circuitry, at a drive line via a drive signal admitting a first value and a second value, output circuitry;
producing, by the output circuitry, the output signal from the arc cell; and
conditioning, by the output circuitry, the propagation of the analog input signal over the FSM circuit upon either one of i) the drive signal recovering its first value after the glitch affecting the analog input signal, the glitch being suppressed at the output of the arc cell, or ii) the drive signal switching from the first value to the second value in response to the glitch affecting the analog input signal with a cell latch signal being asserted in response to the glitch being latched within the arc cell.

14. The method of claim 13, further comprising providing, by a feedback signal on a feedback path in the core circuitry from the drive line to the input of the core circuitry, the cell latch signal asserted in response to the glitch being latched within the arc cell.

15. The method of claim 14, the feedback path from the drive line comprising a logic inverter coupled to the drive line, and the method further comprising carrying, by the feedback path towards the input of the core circuitry, an inverted feedback signal that is a logically-inverted replica of the drive signal admitting the first value and the second value.

16. The method of claim 14, further comprising supplying the output circuitry, by a supply node having applied thereto the feedback signal.

17. An asynchronous finite state machine (FSM) circuit comprising:
an arc cell comprising:
core circuitry configured to receive at an input an analog input signal that is a candidate for propagation over the FSM circuit as an output from the arc cell; and
output circuitry driven by the core circuitry at a drive line via a drive signal admitting a first value and a second value, and configured to:
produce an output signal from the arc cell; and
in response to a glitch affecting the analog input signal, condition the propagation of the analog input signal over the FSM circuit upon either one of i) the drive signal recovering its first value after the glitch affecting the analog input signal, wherein the glitch is suppressed at the output of the arc cell, or ii) the drive signal switching from the first value to the second value in response to the glitch affecting the analog input signal with a cell latch signal being asserted in response to the glitch being latched within the arc cell.

18. The FSM circuit of claim 17, wherein the core circuitry comprises a feedback path from the drive line carrying a feedback signal towards the input of the core circuitry, and wherein the feedback signal provides the cell latch signal asserted in response to the glitch being latched within the arc cell.

19. The FSM circuit of claim 18, wherein the feedback path from the drive line comprises a logic inverter coupled to the drive line, and is configured to carry towards the input of the core circuitry an inverted feedback signal that is a logically-inverted replica of the drive signal admitting the first value and the second value.

20. The FSM circuit of claim 18, wherein the output circuitry is supplied via a supply node configured to have applied thereto the feedback signal.

21. The FSM circuit of claim 17, wherein the output circuitry comprises an inverter including first and second MOSFET transistors having respective control terminals commonly coupled to the drive line from the core circuitry, and wherein the first and second MOSFET transistors are arranged with current flow paths therethrough cascaded to each other with an output node of the arc cell arranged therebetween.
